(19) United States
(12) Patent Application Publication
(10) Pub. No.: US 2017/0018471 A1
(43) Pub. Date: Jan. 19, 2017

(54) Physical Quantity Sensor

(71) Applicant: Hitachi, Ltd., Tokyo (JP)

(72) Inventors: Takanori AONO, Tokyo (JP); Tomonori SEKIGUCHI, Tokyo (JP); Takashi SHIOTA, Tokyo (JP); Yuudai KAMADA, Tokyo (JP); Atsushi ISOBE, Tokyo (JP)

(21) Appl. No.: 15/182,657

(22) Filed: Jun. 15, 2016

(30) Foreign Application Priority Data
Jul. 17, 2015 (JP) 2015-143306

(51) Int. Cl. H01L 23/053; G01L 9/02; G01P 15/18; G01P 3/44; H01L 23/498; B81B 7/00

(52) U.S. Cl. CPC H01L 23/053; H01L 23/49838; H01L 23/49861; B81B 7/0058; G01P 15/18; G01P 3/44; G01L 9/02; B81B 2201/0235; B81B 2201/0242; B81B 2201/0264; B81B 2207/07

(57) ABSTRACT

To provide a physical quantity sensor in which the influence of deformation of a package substrate on the measuring accuracy of a sensor element can be suppressed. A physical quantity sensor includes a sensor element that detects a predetermined physical quantity and outputs an electrical signal, a plurality of lead portions that are connected to the sensor element, and a package substrate that accommodates the sensor element and the plurality of lead portions. The plurality of lead portions are connected at proximal end sides thereof to the package substrate side, and connected at distal end sides thereof to the sensor element side, and the plurality of lead portions support the sensor element in such a manner that the sensor element does not contact the package substrate and that the transmission of deformation of the package substrate side to the sensor element is suppressed.

### TECHNICAL FIELD

The present invention relates to a physical quantity sensor.

### BACKGROUND ART

Physical quantity sensors whose measurement target is a physical quantity such as acceleration are manufactured using a micro-electro-mechanical systems (MEMS) technique. The physical quantity sensor is, for example, a minute three-dimensional structure that is processed using techniques such as deposition, photolithography, and etching to which a semiconductor manufacturing process is applied. When a signal (pressure, acceleration, angular velocity, etc.) from the outside acts on the three-dimensional structure of the physical quantity sensor, the physical quantity sensor outputs an electrical signal in response to the deformation amount of the three-dimensional structure.

A physical quantity sensor disclosed in PTL 1 is composed of beams, a weight, and detection electrodes. In the physical quantity sensor of PTL 1, when a signal (acceleration, angular velocity) from the outside is applied, the weight connected to the beams is driven. The physical quantity sensor detects a change in capacitance between the detection electrodes due to the driving of the weight, and outputs a signal.

As in a physical quantity sensor disclosed in PTL 2, piezoresistive elements may be formed instead of detection electrodes in beams. In the physical quantity sensor disclosed in PTL 2, when a weight is driven by a signal from the outside, the resistance value of the piezoresistive element changes, and as a result of this, a voltage changes. In this manner, the physical quantity sensor can detect a physical quantity as a change in capacitance or a change in voltage.

By the way, when temperature, humidity, unwanted vibration or the like other than a detection target is applied to the physical quantity sensor at the time of detecting a physical quantity as a measurement target, a package substrate or the like is deformed. This deformation adversely affects the measuring accuracy for the physical quantity as an original measurement target.

In PTL 3, in an angular velocity sensor in which a vibration-type angular velocity detecting element is accommodated in a package substrate, the resonant frequency of leads is lowered by lengthening a lead frame. Due to this, in the angular velocity sensor disclosed in PTL 3, the influence of the resonant frequency of the leads on a high resonant frequency (several thousands Hz) is reduced.

In PTL 4, an anti-vibration member is provided between an internal unit and a casing of a dynamic quantity sensor. The dynamic quantity sensor disclosed in PTL 4 absorbs vibration transmitting from the casing with the anti-vibration member, and transmits only vibration as a measurement target to the internal unit.

In NPL 1, an angular velocity sensor chip is mounted in a suspended manner in a packaging by wire bonding. Due to this, in NPL 1, the deformation of a package substrate is prevented from transmitting to the angular velocity sensor chip.

### CITATION LIST

### Patent Literature

PTL 1: JP-A-2010-243479

PTL 2: JP-A-2002-296293

PTL 3: JP-A-2007-64753

PTL 4: JP-A-2010-181392

### Non Patent Literature

NPL 1: TRANSDUCERS 2013, pp. 1962-1965

### SUMMARY OF INVENTION

### Technical Problem

In PTL 3, the leads are placed on two facing sides of the sides of the package substrate on which the detecting element is mounted, and therefore, the influence of an unwanted signal from a direction in which the leads are placed can be suppressed. However, the sensor of PTL 3 is susceptible to the influence of an unwanted signal caused by twist or tilt toward a direction in which the leads are not disposed.

In the dynamic quantity sensor disclosed in PTL 4, since the anti-vibration member is provided between the sensor element and the casing, there is a risk that the deformation of the anti-vibration member affects a detection signal of the dynamic quantity sensor.

In NPL 1, although the sensor chip is suspended by a bonding wire, there is a risk that the wire may be broken due to vibration or the like applied to the sensor, and there is room for improvement in terms of durability or reliability.

The invention has been made focusing on the problem described above, and it is an object of the invention to provide a physical quantity sensor in which the influence of deformation of a package substrate on the measuring accuracy of a sensor element can be suppressed.

### Solution to Problem

To solve the above problem, a physical quantity sensor according to the invention is a physical quantity sensor that measures a physical quantity, including: a sensor element that detects a predetermined physical quantity and outputs an electrical signal; a plurality of lead portions that are connected to the sensor element; and a package substrate that accommodates the sensor element and the plurality of lead portions, wherein the plurality of lead portions are connected at proximal end sides thereof to the package substrate side, and connected at distal end sides thereof to the sensor element side, and the plurality of lead portions support the sensor element in such a manner that the sensor element does not contact the package substrate and that the transmission of deformation of the package substrate side to the sensor element is suppressed.

### Advantageous Effects of Invention

According to the invention, since the plurality of lead portions support the sensor element in such a manner that the sensor element does not contact the package substrate and that the transmission of deformation of the package substrate side to the sensor element is suppressed, the influence of deformation of the package substrate on a detection signal of the sensor element is reduced, and thus the measuring accuracy of the sensor element can be increased.

### BRIEF DESCRIPTION OF DRAWINGS

FIG. 1 is an exploded perspective view of a physical quantity sensor according to a first example.

FIGS. 2A and 2B are cross-sectional views of the physical quantity sensor.

FIG. 3 is an exploded perspective view of a physical quantity sensor according to a second example.

FIGS. 4A and 4B are cross-sectional views of the physical quantity sensor.

FIG. 5 is an exploded perspective view of a physical quantity sensor according to a third example.

FIGS. 6A and 6B are cross-sectional views of the physical quantity sensor.

FIG. 7 is a plan view of a lead substrate of a physical quantity sensor according to a fourth example.

FIG. 8 is a cross-sectional view of a physical quantity sensor according to a fifth example.

### DESCRIPTION OF EMBODIMENTS

Hereinafter, an embodiment of the invention will be described based on the drawings. In the embodiment, as will be described in detail below, the influence of a physical quantity (temperature, humidity, unwanted vibration) other than a measurement target on a physical quantity sensor chip 10 is suppressed. To this end, in the embodiment, the physical quantity sensor chip 10 as a “sensor element” is placed on a lead substrate 20 having a rectangular shape. Hereinafter, the physical quantity sensor chip 10 is sometimes abbreviated as the sensor chip 10.

Leads 22 as “lead portions” are disposed at predetermined intervals on each of four sides of the lead substrate 20. The lead substrate 20 is suspended in a package substrate 30 by means of the leads 33 extending from the four sides. The surface of the sensor chip 10 and the rear surface of the lead substrate 20 are slightly separated respectively from the inner surfaces of the package substrate 30, so that predetermined gaps are formed.

The sensor chip 10 and the lead substrate 20 are supported in a suspended state in the hollow package substrate 30, and are not in contact with the package substrate 30. For this reason, the influence of an impact or deformation applied to the package substrate 30 on the sensor chip 10 can be suppressed.

Further, the gap formed between the surface of the sensor chip 10 and the inner surface of the package substrate 30 and the gap formed between the rear surface of the lead substrate 20 and the inner surface of the package substrate 30 are used as so-called gas dampers, so that vibration transmitting from the package substrate 30 to the sensor chip 10 or the lead substrate 20 can be attenuated.

Further, the plurality of leads 22 are disposed at predetermined intervals on the four sides of the lead substrate 20 formed into a rectangular shape, which is a symmetrical shape, and therefore symmetrically support the lead substrate 20 and the sensor chip 10 from four directions. For this reason, in the embodiment, the transmission of twist or tilt caused in the package substrate 30 to the sensor chip 10 can be suppressed. In other words, in the embodiment, since vibration, twist, or tilt caused in the package substrate 30 can be absorbed by the plurality of leads 22, the influence of a physical quantity other than a measurement target is reduced, and S/N can be increased.

Further, a difference between the linear expansion coefficient of the sensor chip 10 and the linear expansion coefficient of the lead substrate 20 is set to be small, or a predetermined board 50 having a linear expansion coefficient similar to that of the sensor chip 10 may be provided on a surface of both surfaces of the lead substrate 20, which is on the side opposite to the surface on which the sensor chip 10 is mounted. The predetermined board 50 is, for example, an amplifier circuit board that amplifies a detection signal of the sensor chip 10. Due to this, the deformation of the lead substrate 20 due to thermal expansion can be suppressed. When the linear expansion coefficients of the sensor chip 10 and the lead substrate 20 are approximately equal to each other, the deformation of the lead substrate 20 can be suppressed even when temperature changes. When the linear expansion coefficients of the sensor chip 10 and the lead substrate 20 are different from each other, the predetermined board having a linear expansion coefficient similar to that of the sensor chip 10 is provided on the surface of both surfaces of the lead substrate 20, which is opposite to the mounting surface of the sensor chip 10. Due to this, even when a temperature change occurs, the thermal expansion of the sensor chip 10 caused on one surface of the lead substrate 20 and the thermal expansion of the predetermined board 50 caused on the other surface of the lead substrate 20 can be eventually cancelled out, and thus the deformation of the lead substrate 20 and the sensor chip 10 can be suppressed.

Further in the embodiment, since the leads 22 are formed as a lead frame having a rigidity higher than that of a bonding wire, the lead substrate 20 on which the sensor chip 10 is placed can be supported uniformly and firmly. Hereinafter, the embodiment will be described in detail.

### EXAMPLE 1

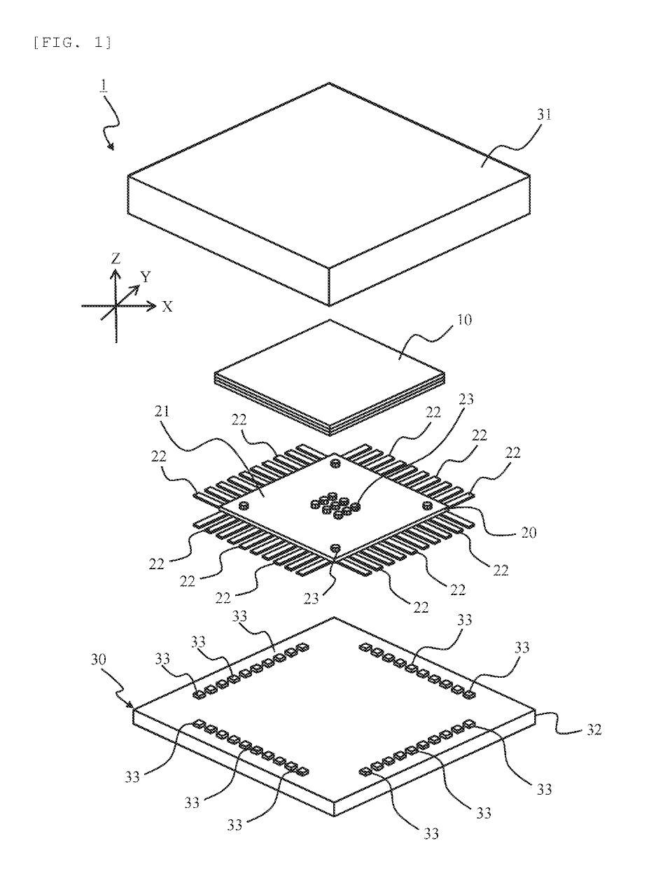

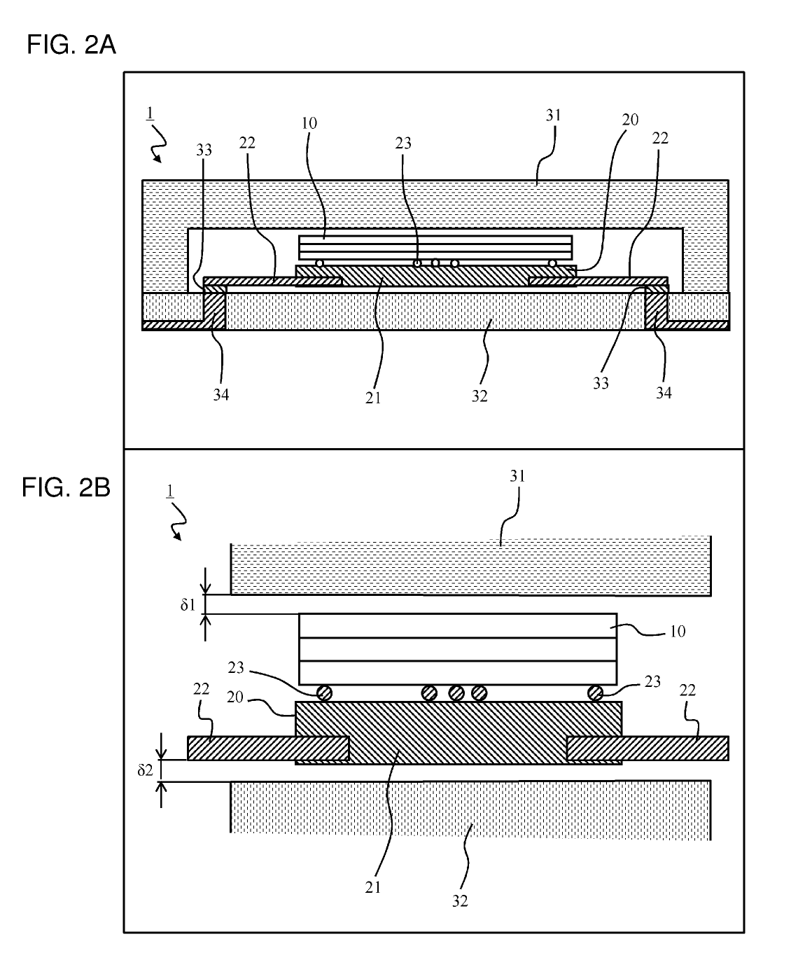

A first example will be described using FIGS. 1 and 2. FIG. 1 is an exploded perspective view of a physical quantity sensor 1 according to the example. FIG. 2 are cross-sectional views of the physical quantity sensor.

The physical quantity sensor 1 is, for example, a device that detects a predetermined physical quantity (physical quantity as a measurement target) such as acceleration or angular velocity, and outputs a signal. The physical quantity sensor 1 is configured to include, for example, the sensor chip 10, the lead substrate 20, and the package substrate 30.

When a physical quantity as a measurement target is applied, a three-dimensional structure in the interior of the sensor chip 10 is deformed, and the sensor chip 10 outputs an electrical signal. The sensor chip 10 uses a change in capacitance or a change in resistance in response to the deformation of the three-dimensional structure to convert the deformation into an electrical signal. The sensor chip 10 is formed into a symmetrical shape. Examples of the symmetrical shape include, in a plan view, an oblong, a square, an isosceles triangle, a regular triangle, a circle, and an ellipse. A square or a circle is one of preferable shapes for the sensor chip 10. However, the sensor chip 10 is not limited to a square or a circle.

The lead substrate 20 is a substrate for electrically connecting the sensor chip 10 with the package substrate 30 to connect the sensor chip 10 to an external system outside the figure. The lead substrate 20 includes, for example, an electrode substrate 21, the leads 22, and connecting elements 23.

The electrode substrate 21 is formed into a symmetrical shape from a material having a linear expansion coefficient similar to that of the sensor chip 10. Examples of the symmetrical shape include, in the plan view, for example an oblong, a square, an isosceles triangle, a regular triangle, a circle, and an ellipse. A square or a circle is one of preferable shapes for the electrode substrate 21 of the lead substrate 20. However, the shape of the electrode substrate 21 is not limited to a square or a circle.

In the example, the sensor chip 10 and the electrode substrate 21 of the lead substrate 20 are both formed into the same symmetrical shape (a square herein). Then, equal numbers of the plurality of leads 22 are disposed at predetermined intervals on respective four sides constituting the peripheral edge of the electrode substrate 21. The leads 22 are formed as a lead frame having a rigidity higher than that of a bonding wire.

A proximal end side of each of the leads 22 is electrically connected to an electrode 33 of the package substrate 30 with solder or the like. A distal end side of each of the leads 22 is electrically connected via a wiring pattern (not shown) of the electrode substrate 21 to the sensor chip 10 with solder or the like. Note that the leads 22 are fixed to the electrode substrate 21 with solder or the like and thereby mechanically connected to the sensor chip 10. The leads 22 uniformly support the sensor chip 10 in a suspended manner in the package substrate 30, via the electrode substrate 21 of the lead substrate 20, from the four sides of the electrode substrate 21.

The connecting elements 23 for electrically connecting with an electric circuit in the sensor chip 10 are disposed at predetermined positions on the surface (upper surface in FIG. 1) of the electrode substrate 21.

The package substrate 30 has a hollow sealed structure to accommodate the sensor chip 10 and the lead substrate 20. The package substrate 30 is formed into a square (in the plan view) as a symmetrical shape, similarly to the sensor chip 10 and the lead substrate 20.

The package substrate 30 includes, for example, a lid portion 31 and a substrate portion 32. The electrodes 33 are disposed on the surface of the substrate portion 32 of the package substrate 30. The electrodes 33 are electrically connected to the external system outside the figure via other electrodes 34 shown in FIG. 2. The sensor chip 10 is electrically connected to the external system via the lead substrate 20 and the package substrate 30.

An example of the manufacturing process of the physical quantity sensor 1 will be briefly described. Firstly, the sensor chip 10, the lead substrate 20, and the package substrate 30 are manufactured and prepared. Secondly, the sensor chip 10 is mounted on the lead substrate 20, and the sensor chip 10 and the lead substrate 20 are electrically and mechanically connected. Thirdly, the lead substrate 20 on which the sensor chip 10 is mounted is electrically and mechanically connected to the substrate portion 32 of the package substrate 30. Fourthly, the lid portion 31 is hermetically attached to the substrate portion 32 so as to cover the substrate portion 32. The package substrate 30 is hermetically sealed in a state where an inert gas or dry air is enclosed in the interior thereof.

Reference is made to FIG. 2. FIG. 2(a) is a cross-sectional view of the physical quantity sensor 1 after assembling. FIG. 2(b) is a cross-sectional view showing, in an enlarged manner, a portion of FIG. 2(a).

The lead substrate 20 on which the sensor chip 10 is mounted is supported in a suspended state in the package substrate 30 by the leads 22 extending from the four sides. Other portions except the proximal end sides of the leads 22 connected to the substrate portion 32 of the package substrate 30, that is, the sensor chip 10 and the electrode substrate 21, are supported by the leads 22 in such a state as to float in the air without contacting the package substrate 30.

A minute gap δ1 is formed between the surface (upper surface in FIG. 2) of the sensor chip 10 and the rear surface of the lid portion 31 of the package substrate 30. Another minute gap δ2 is formed between the lower surface of the electrode substrate 21 of the lead substrate 20 and the upper surface of the substrate portion 32 of the package substrate 30. These gaps δ1 and δ2 are set to, for example, values of from several μm to ten and several μm.

According to the example configured as described above, even when the package substrate 30 is deformed due to a change in temperature or humidity, the leads 22 absorb the deformation through a slight deflection or the like. Therefore, the influence of deformation of the package substrate 30 on the sensor chip 10 can be suppressed. As a result of this, the physical quantity sensor of the example can improve measuring accuracy and reliability even when the physical quantity sensor is downsized or thinned.

According to the example, the lead substrate 20 on which the sensor chip 10 is mounted is supported in a suspended state in such a manner that the lead substrate 20 except the proximal end sides of the leads 22 is not contact with the package substrate 30, in the package substrate 30 with a hollow structure. Then, the gap δ1 is formed between the sensor chip 10 and the lid portion 31 of the package substrate 30, and the gap δ2 is formed between the lead substrate 20 and the substrate portion 32 of the package substrate 30. That is, in the example, the minute gaps δ1 and δ2 are formed respectively above and below a structure of the sensor chip 10 and the lead substrate 20, and the gaps δ1 and δ2 function as gas dampers. Therefore, in the example, when unwanted vibration is applied to the physical quantity sensor 1, the unwanted vibration can be reduced by damping effects of gases caused in the gaps δ1 and δ2. For this reason, the intensity of a signal for the sensor chip 10 to detect the unwanted vibration is made smaller than the intensity of a signal of a physical quantity as a measurement target, so that S/N can be increased.

In the example, even when a resonant frequency is applied to a three-dimensional structure in which the sensor chip 10 and the lead substrate 20 are weights and the leads 22 are springs, the transmission of vibration due to the resonant frequency to the sensor chip 10 can be suppressed by the gas damper effects of the gaps δ1 and δ2.

In the example, since the leads 22 extracted from the electrode substrate 21 of the lead substrate 20 are disposed in the directions of the four sides of the electrode substrate 21, the deformation of the lead substrate 20 when unwanted vibration is applied to the package substrate 30 can also be suppressed. Since the lead substrate 20 on which the sensor chip 10 is mounted is uniformly supported at the four sides by the leads 22 having a high rigidity, the rotation of the sensor chip 10 and the lead substrate 20 about the Z-axis in FIG. 1, the rotation thereof about the X-axis, or the rotation thereof about the Y-axis can be suppressed. Then, as described above, when the whole of the sensor chip 10 and the lead substrate 20 is displaced in the vertical direction (Z-axis direction), the gaps δ1 and δ2 block the movement in the vertical direction, and therefore, the displacement amount in the vertical direction can be reduced.

### EXAMPLE 2

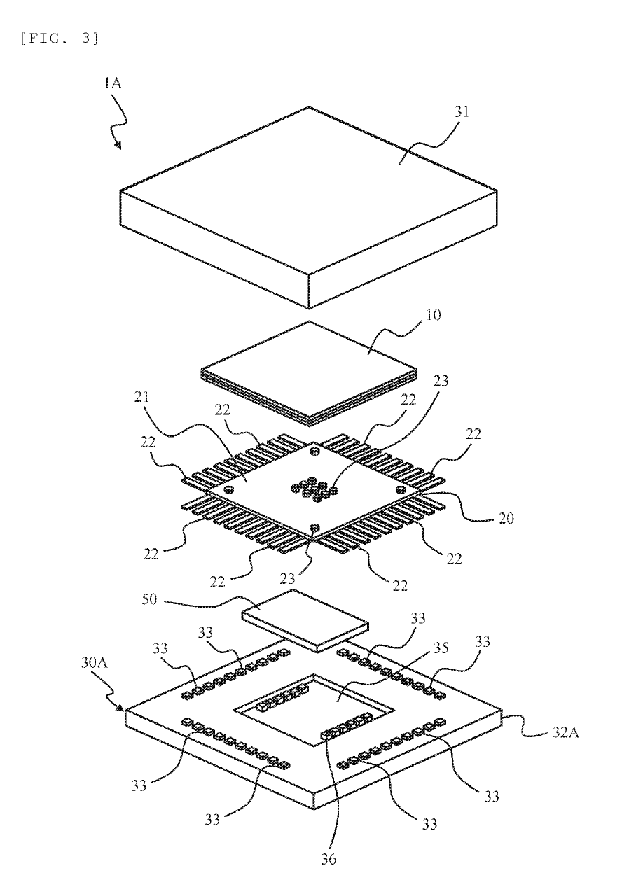

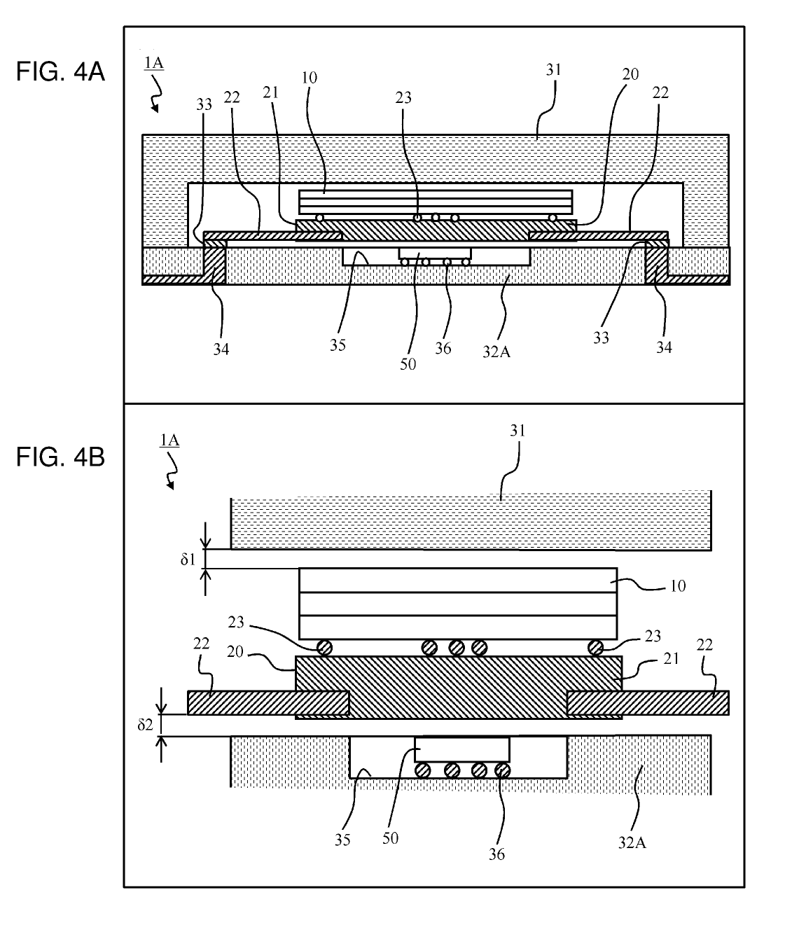

A second example will be described with reference to FIGS. 3 and 4. The following examples including the example correspond to modified examples of the first example, and therefore, the differences from the first example will be mainly described. A physical quantity sensor 1A of the example incorporates the amplifier circuit board 50 therein. FIG. 3 is an exploded perspective view of the physical quantity sensor 1A. FIG. 4 are cross-sectional views of the physical quantity sensor 1A.

The physical quantity sensor 1A is configured to include the sensor chip 10, the lead substrate 20, a package substrate 30, and the amplifier circuit board 50. The amplifier circuit board 50, which is an example of the “predetermined board” that processes a signal from the sensor chip 10, amplifies a signal of the sensor chip 10 and outputs the signal. Hereinafter, the amplifier circuit board 50 is sometimes abbreviated as the circuit board 50.

The circuit board 50 is formed into a square or an oblong as a symmetrical shape. The circuit board 50 is accommodated in a circuit board accommodating portion 35 formed at the center of a substrate portion 32A of the package substrate 30A, and is electrically connected with electrodes 36 provided on the substrate portion 32A. The sensor chip 10 is connected from, for example, the leads 22 via the electrodes 33 of the package substrate 30 to a wiring pattern (not shown) in the substrate portion 32, and is connected from the wiring pattern via the electrodes 36 to the circuit board 50.

An example of the manufacturing process of the physical quantity sensor 1A will be described. Firstly, the sensor chip 10, the lead substrate 20, and the package substrate 30 are manufactured and prepared. Secondly, the sensor chip 10 is mounted on the lead substrate 20, and the sensor chip 10 and the lead substrate 20 are electrically and mechanically connected. Thirdly, the circuit board 50 is mounted on the accommodating portion 35 of the package substrate 30, and electrically connected with the electrodes 36. Fourthly, the lead substrate 20 on which the sensor chip 10 is mounted is electrically and mechanically connected to the substrate portion 32 of the package substrate 30. Fifthly, the lid portion 31 is hermetically attached to the substrate portion 32 so as to cover the substrate portion 32. The package substrate 30 is hermetically sealed in a state where an inert gas or dry air is enclosed in the interior thereof.

Also in the example, the minute gap δ1 is formed between the upper surface of the sensor chip 10 and the lid portion 31 of the package substrate 30. Further, the minute gap δ2 is also formed between the lower surface of the electrode substrate 21 of the lead substrate 20 and the substrate portion 32 of the package substrate 30. More specifically, in the example, since the circuit board 50 is accommodated in the accommodating portion 35 at the central portion of the substrate portion 32, the gap δ2 is defined as a gap between the upper surface of the circuit board 50 or the upper surface of the substrate portion 32, whichever is a higher surface, and the lower surface of the electrode substrate 21 of the lead substrate 20. That is, the sensor chip 10 and the lead substrate 20 are also not in contact with the circuit board 50.

The example configured as described above also provides operational effects similar to those of the first example. Further, since the physical quantity sensor 1A of the example incorporates the circuit board 50 therein, a signal of the sensor chip 10 can be amplified and output to the external system, and thus convenience is improved. The circuit board 50 may include a circuit that exerts a function other than that of an amplifier circuit. For example, a waveform shaping circuit, a noise filtering circuit or the like may be included in the circuit board 50, or an analog/digital conversion circuit or the like may be included in the circuit board 50.

### EXAMPLE 3

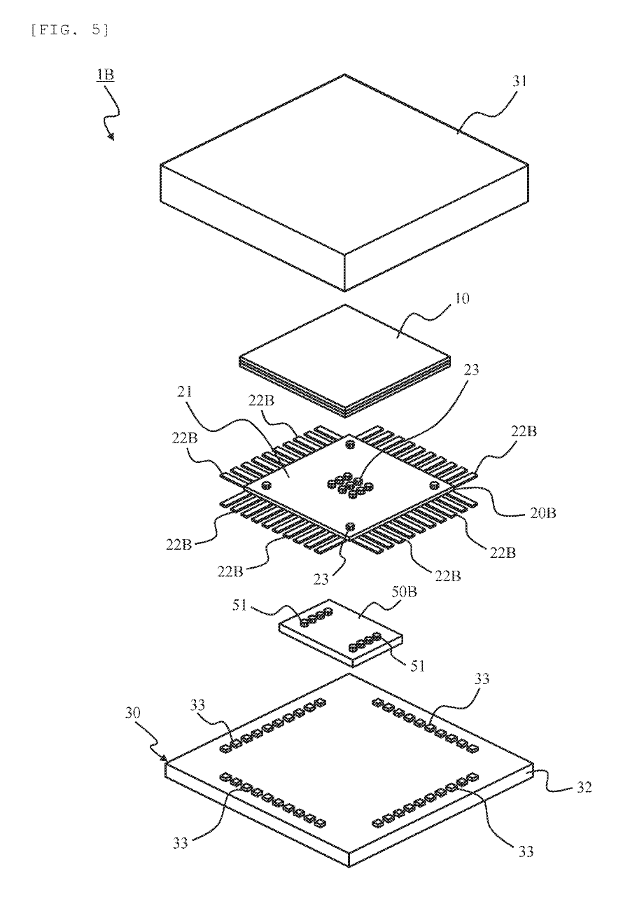

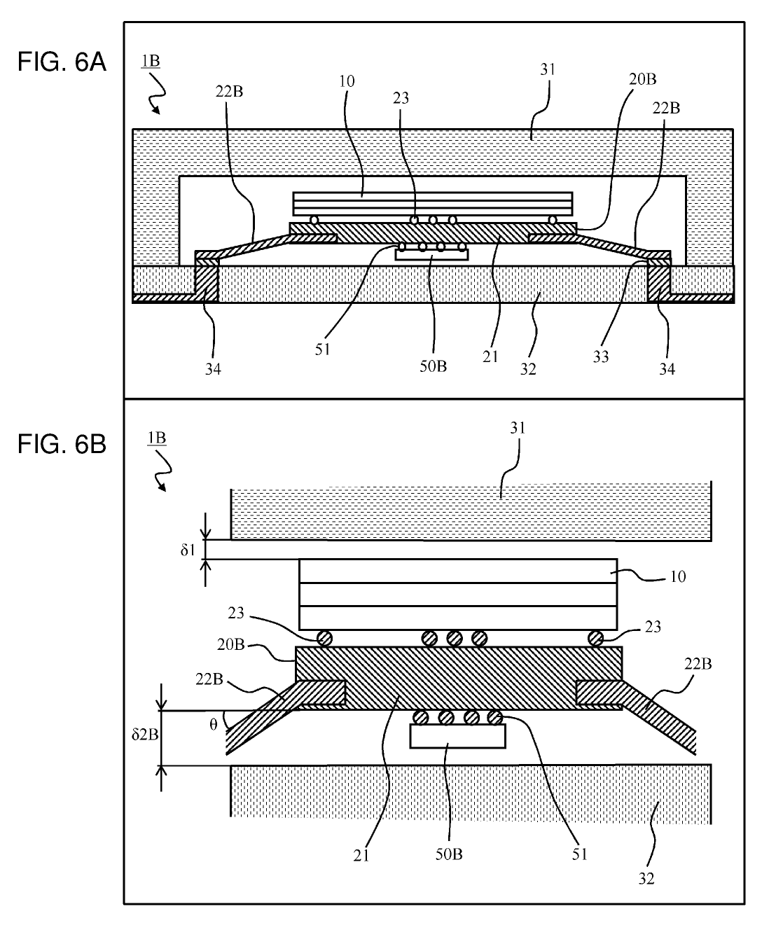

A third example will be described using FIGS. 5 and 6. A physical quantity sensor 1B of the example includes a circuit board 50B mounted on the lower surface of the electrode substrate 21 of a lead substrate 20. Further, in the physical quantity sensor 1B of the example, leads 22 are slightly bent so as to forma space for disposing the circuit board 50B between the lower surface of the electrode substrate 21 and the upper surface of the substrate portion 32. FIG. 5 is an exploded perspective view of the physical quantity sensor 1B. FIG. 6 are cross-sectional views of the physical quantity sensor 1B.

The physical quantity sensor 1B is configured to include the sensor chip 10, the lead substrate 20B, the package substrate 30, and the circuit board 50B. The leads 22B are bent obliquely downward and extracted, as shown in FIG. 6, from the four sides of the electrode substrate 21 of the lead substrate 20B.

When the electrode plate 21 is assumed as a reference horizontal plane, the lead 22B extends obliquely downward by an angle θ from the horizontal plane. A distal end side of the lead 22B is a flat portion connected to the electrode plate 21, and a proximal end side of the lead 22B is a flat portion connected to the electrode 33 of the package substrate 30.

The lead substrate 20B on which the sensor chip 10 is mounted is supported, by the leads 22B obliquely bent by the angle θ from the horizontal direction, in a suspended state in the package substrate 30 with a hollow structure. A gap δ2B between the electrode substrate 21 of the lead substrate 20 and the substrate portion 32 of the package substrate 30 is larger than the gap δ2 in the examples described above (δ2B>δ2) by an amount corresponding to the inclination of the leads 22B. The circuit board 50B is mounted at the central portion of the lower surface of the electrode plate 21 while being located in this expanded gap δ2B.

The circuit board 50B, which is another example of the “predetermined board”, is formed into a square or an oblong as asymmetrical shape. The circuit board 50B may be an amplifier circuit board that amplifies a signal from the sensor chip 10, or may be a circuit board that realizes a function other than amplification. On the circuit board 50B, a plurality of electrodes 51 for electrically connecting with the lead substrate 20B are formed.

The circuit board 50B is located at substantially the central portion of the electrode plate 21 of the lead substrate 20, and fixed to the lower surface by soldering or the like. The circuit board 50B is formed so as to have a linear expansion coefficient approximately the same as that of the sensor chip 10. Due to this, even when a temperature change occurs in the physical quantity sensor 1B, a displacement due to the thermal expansion of the sensor chip 10 and a displacement due to the thermal expansion of the circuit board 50B are cancelled out by each other as viewed from the lead substrate 20. Therefore, the displacement amount of the lead substrate 20 can be reduced, and an influence due to a difference between the linear expansion coefficients on the sensor chip 10 can be suppressed. Note that if not only are the respective linear expansion coefficients of the sensor chip 10 and the circuit board 50B set approximately equal to each other, but also the linear expansion coefficient of the electrode substrate 21 of the lead substrate 20 is made approximately equal to the linear expansion coefficients, the influence due to thermal expansion can be still further reduced.

An example of the manufacturing process of the physical quantity sensor 1B will be described. Firstly, the sensor chip 10, the lead substrate 20B, and the package substrate 30 are manufactured and prepared. Secondly, the sensor chip 10 is mounted on the lead substrate 20B, and the sensor chip 10 and the lead substrate 20B are electrically and mechanically connected. Thirdly, the circuit board 50B is mounted on the lead substrate 20B, and the circuit board 50B and the lead substrate 20B and the sensor chip 10 are electrically connected via the electrodes 51. Fourthly, the lead substrate 20B on which the sensor chip 10 and the circuit board 50B are mounted is electrically and mechanically connected to the substrate portion 32 of the package substrate 30. Fifthly, the lid portion 31 is hermetically attached to the substrate portion 32 so as to cover the substrate portion 32. The package substrate 30 is hermetically sealed in a state where an inert gas or dry air is enclosed in the interior thereof.

The example configured as described above also provides operational effects similar to those of the first and second examples. Further in the example, since the circuit board 50B is mounted on the lead substrate 20B while being located on the side opposite to the sensor chip 10, a wiring pattern length between the circuit board 50B and the sensor chip 10 can be shortened. Therefore, the superimposition of noise on the signal of the sensor chip 10 can be suppressed, so that reliability and usability can be still further improved.

### EXAMPLE 4

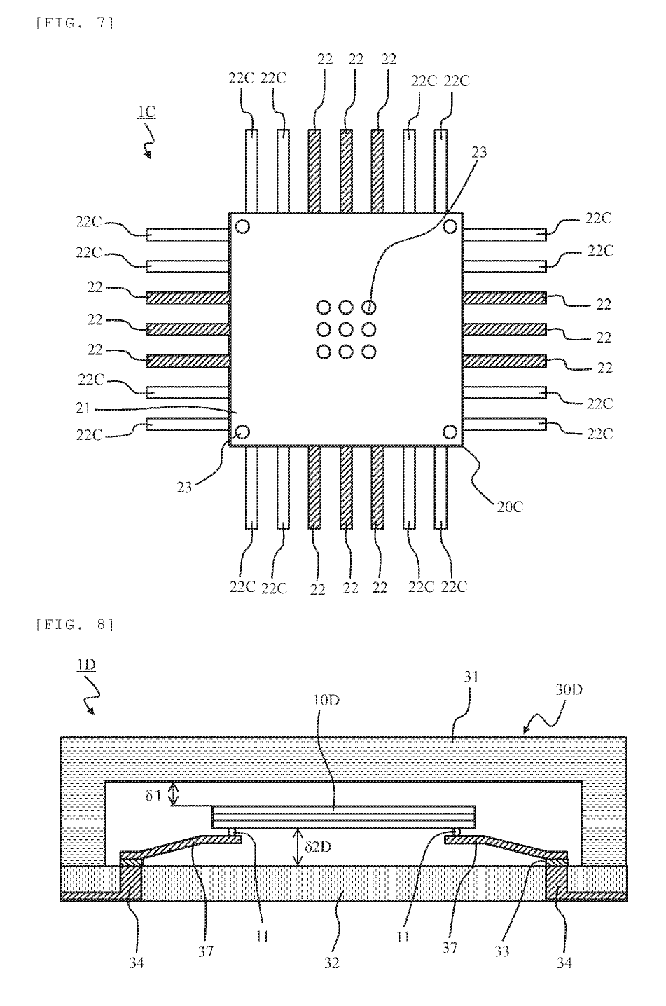

A fourth example will be described using FIG. 7. In a physical quantity sensor 1C of the example, the leads 22 as “first lead portions” and dummy leads 22C as “second lead portions” are extracted from the electrode substrate 21 of a lead substrate 20C. In FIG. 7, the leads 22 are hatched to distinguish them from the dummy leads 22C.

The leads 22 electrically connect the sensor chip 10 with the package substrate 30 as described above, and also mechanically connect the sensor chip 10 to the package substrate 30 via the electrode substrate 21.

In contrast to this, the dummy leads 22C only mechanically connect the sensor chip 10 to the package substrate 30 via the electrode substrate 21, so that the dummy leads 22C are not electrically connected to the sensor chip 10. That is, the dummy leads 22C function only as beams for support, and do not constitute an electric circuit.

Since an electrical signal flows through the normal lead 22, a distal end of the lead 22 is provided on the electrode plate 21 while being located in a predetermined region to which a stress due to a temperature change is hardly applied. The predetermined region is, for example, the central portion of each of the four sides of the electrode substrate 21. Since the displacement amount due to thermal expansion is less at the central portion of the electrode plate 21, a stress applied to the lead 22 can be made small. As a result of this, the superimposition of noise on the signal flowing through the lead 22 can be suppressed.

The example configured as described above also provides operational effects similar to those of the first example. The example can also be combined with any of the second and third examples. According to the example, the normal leads 22 are disposed in the region to which the stress is relatively hardly applied, while the dummy leads 22C through which a signal does not flow are disposed in a region to which the stress is relatively applied; and therefore, reliability can be still further improved.

### EXAMPLE 5

A fifth example will be described using FIG. 8. FIG. 8 is a cross-sectional view of a physical quantity sensor 1D. In the physical quantity sensor 1D of the example, the lead substrate 20 is removed, and a sensor chip 10D and a package substrate 30D are directly connected via a plurality of leads 37.

A plurality of electrodes 11 are provided on the lower surface of the sensor chip 10D. The leads 37 corresponding to the electrodes 11 are bent obliquely upward and extracted from the substrate portion 32 of the package substrate 30D. A signal detected by the sensor chip 10D is sent to the external system via the electrodes 11, the leads 37, the electrodes 33, and the electrodes 34.

The gap δ1 is formed between the upper surface of the sensor chip 10D and the lid portion 31 of the package substrate 30D. Also, a gap δ1D is formed between the lower surface of the sensor chip 10D and the substrate portion 32 of the package substrate 30D.

The example configured as described above also provides operational effects similar to those of the first example. The example can be combined with any of the second, third, and fourth examples. In the example, since the lead substrate 20 is removed, the configuration of the physical quantity sensor 1D can be simplified, and thus the manufacturing cost can be reduced.

Note that the invention is not limited to the embodiment described above. Those skilled in the art can make various additions, modifications or the like within the scope of the invention. The features described in each of the examples can be used in appropriate combination with the configurations of the other examples. For example, the sensor chip and the lead substrate may be integrally formed.

### REFERENCE SIGN LIST

1, 1A, 1B, 1C, 1D: physical quantity sensor
10, 10D: sensor chip
20, 20B, 20C: lead substrate
22, 22B, 22C: lead
30, 30A, 30D: package substrate
37: lead
50, 50B: circuit board

1. A physical quantity sensor that measures a physical quantity, comprising:
a sensor element, that detects a predetermined physical quantity and outputs an electrical signal;
a plurality of lead portions that are connected to the sensor element; and
a package substrate that accommodates the sensor element and the plurality of lead portions, wherein
the plurality of lead portions are connected at proximal end sides thereof to the package substrate side, and connected at distal end sides thereof to the sensor element side, and
the plurality of lead portions support the sensor element in such a manner that the sensor element does not contact the package substrate and that the transmission of deformation of the package substrate side to the sensor element is suppressed.

2. The physical quantity sensor according to claim 1, wherein
the package substrate has a hermetic structure, and a gas damper is formed in a gap between the sensor element and the package substrate due to a gas enclosed in the package substrate.

3. The physical quantity sensor according to claim 2, wherein
the plurality of lead portions symmetrically support the sensor element.

4. The physical quantity sensor according to claim 3, wherein
the sensor element, has a symmetrical shape,
the plurality of lead portions are disposed at predetermined intervals on a peripheral edge side of the sensor element, and
the plurality of lead portions uniformly support the sensor element.

5. The physical quantity sensor according to claim 4, wherein
the plurality of lead portions are provided on a lead substrate,
the sensor element is mounted on the lead substrate, and
the plurality of lead portions support the sensor element via the lead substrate.

6. The physical quantity sensor according to claim 5, wherein
a difference between a linear expansion coefficient of the lead substrate and a linear expansion coefficient of the sensor element is set to be small, or a predetermined board having a linear expansion coefficient similar to that of the sensor element is provided on one surface of both surfaces of the lead substrate, which is on the side opposite to the other surface on which the sensor element is mounted.

7. The physical quantity sensor according to claim 6, wherein
the predetermined board is a board that processes an output signal from the sensor element.

8. The physical quantity sensor according to claim 7, wherein
the plurality of lead portions are formed as a lead frame having a rigidity higher than that of a bonding wire.

9. The physical quantity sensor according to claim 8, wherein
the plurality of lead portions include a plurality of first lead portions electrically and mechanically connected to the sensor element and a plurality of second lead portions mechanically connected to the sensor element.

10. The physical quantity sensor according to claim 9, wherein
a distal end side of each of the first lead portions is provided in a predetermined region where a stress when a force is applied to the lead substrate is small in the lead substrate.

11. The physical quantity sensor according to claim 5, wherein
the lead substrate is formed into a rectangular shape in a plan view, and
the plurality of lead portions are disposed at predetermined intervals on four sides of the lead substrate.
